(19) United States
(12) Patent Application Publication
(10) Pub. No.: US 2026/0068531 A1
(43) Pub. Date: Mar. 5, 2026

(54) COMPOSITE SUBSTRATE AND METHOD OF PRODUCING COMPOSITE SUBSTRATE

(71) Applicant: NGK INSULATORS, LTD., Nagoya-shi (JP)

(72) Inventors: Yudai UNO, Nagoya-shi (JP); Masahiro SAKAI, Nagoya-shi (JP); Makoto TANI, Inazawa-shi (JP); Masahiko NAMERIKAWA, Seto-shi (JP)

(21) Appl. No.: 19/383,924

(22) Filed: Nov. 10, 2025

Related U.S. Application Data
(63) Continuation of application No. PCT/JP2024/018664, filed on May 21, 2024.

(30) Foreign Application Priority Data
May 24, 2023 (JP) 2023-085448

(51) Int. Cl. H10N 30/85; H10N 30/06; H10N 30/072; H10N 30/082; H10N 30/097; H10N 30/50; H10N 30/853; H10N 30/87

(52) U.S. Cl. CPC H10N 30/852; H10N 30/06; H10N 30/072; H10N 30/082; H10N 30/097; H10N 30/508; H10N 30/8554; H10N 30/87

(57) ABSTRACT

A composite substrate includes: a support substrate; and a piezoelectric film which is arranged above the support substrate, and includes a polycrystalline substance, wherein a dissimilar material portion including a material different from a material for forming the polycrystalline substance is formed at an end portion on at least one of an upper surface side or a lower surface side of the piezoelectric film.

### CROSS-REFERENCE TO RELATED APPLICATIONS

This application is a continuation under 35 U.S.C. 120 of International Application PCT/JP2024/018664 having the International Filing Date of May 21, 2024 and having the benefit of the earlier filing date of Japanese Application No. 2023-085448 filed on May 24, 2023. Each of the identified applications is fully incorporated herein by reference.

### BACKGROUND OF THE INVENTION

### 1. Field of the Invention

The present disclosure relates to a composite substrate and a method of producing a composite substrate.

### 2. Description of the Related Art

A piezoelectric actuator that vibrates an electro-mechanical conversion film has been put into practical use in a liquid droplet ejection head of an ink jet recording apparatus. In recent years, the piezoelectric actuator has been expected to be applied to other uses (e.g., a MEMS mirror device for a head-up display). In a piezoelectric element used in the piezoelectric actuator, for example, as disclosed in Patent Literature 1, there is used a composite substrate including a lower electrode formed on a substrate, a piezoelectric layer formed on the lower electrode, and an upper electrode formed on the piezoelectric layer.

### CITATION LIST

### Patent Literature

[PTL 1] WO 2017/043383 A1

### SUMMARY OF THE INVENTION

When the method as disclosed in Patent Literature 1 is used to produce the above-mentioned composite substrate, the piezoelectric layer may be formed thin by film formation, but for example, a warp is liable to occur, which leads to a decrease in reliability and yield of the obtained composite substrate (piezoelectric element).

The present disclosure has been made in view of the foregoing, and has a primary object to provide a composite substrate excellent in reliability with good yield.

1. According to an embodiment of the present disclosure, there is provided a composite substrate, including: a support substrate; and a piezoelectric film which is arranged above the support substrate, and includes s a polycrystalline substance, wherein a dissimilar material portion including a material different from a material for forming the polycrystalline substance is formed at an end portion on at least one of an upper surface side or a lower surface side of the piezoelectric film.

2. In the composite substrate according to the above-mentioned item 1, the dissimilar material portion may be formed in a recessed portion in which an end surface of the piezoelectric film is recessed inward in a thickness direction.

3. In the composite substrate according to the above-mentioned item 1 or 2, the piezoelectric film may have a space formed apart from the dissimilar material portion.

4. In the composite substrate according to any one of the above-mentioned items 1 to 3, the dissimilar material portion may have a gap formed adjacent thereto.

5. In the composite substrate according to any one of the above-mentioned items 1 to 4, the dissimilar material portion may be in contact with a layer or a member arranged adjacent to the piezoelectric film.

6. In the composite substrate according to any one of the above-mentioned items 1 to 5, the piezoelectric film may include a polycrystalline substance having a degree of c-axis orientation determined by a Lotgering method of 80% or less.

7. In the composite substrate according to any one of the above-mentioned items 1 to 6, the piezoelectric film may include a sintered body.

8. In the composite substrate according to any one of the above-mentioned items 1 to 7, the piezoelectric film may contain a PZT-based compound.

9. In the composite substrate according to any one of the above-mentioned items 1 to 8, the piezoelectric film may contain a ternary PZT.

10. In the composite substrate according to any one of the above-mentioned items 1 to 9, the piezoelectric film may have a thickness of 1 μm or more and 50 μm or less.

11. According to an embodiment of the present disclosure, there is provided a piezoelectric device, including the composite substrate of any one of the above-mentioned items 1 to 10.

12. According to an embodiment of the present disclosure, there is provided a method of producing a composite substrate, including: preparing a piezoelectric substrate including a sintered body and having an upper surface and a lower surface that face each other; laminating a dissimilar material layer including a material different from a material for forming the piezoelectric substrate on a side of at least one of the upper surface or the lower surface of the piezoelectric substrate to charge a dissimilar material to a recessed portion formed at an end portion of the piezoelectric substrate in a thickness direction; and joining the piezoelectric substrate and a support substrate to each other.

13. The method of producing a composite substrate according to the above-mentioned item 12 may further include removing, in the thickness direction, at least a part of the laminated dissimilar material layer.

According to the embodiment of the present disclosure, it is possible to provide the composite substrate excellent in reliability with good yield.

### BRIEF DESCRIPTION OF THE DRAWINGS

FIG. 1 is a schematic sectional view for illustrating the schematic configuration of a composite substrate according to a first embodiment of the present disclosure.

FIG. 2 is a schematic enlarged sectional view for illustrating the configuration of another example of a dissimilar material portion.

FIG. 3 is a schematic enlarged sectional view for illustrating the configuration of another example of the dissimilar material portion.

FIG. 4 is a schematic sectional view for illustrating the schematic configuration of a composite substrate according to a second embodiment of the present disclosure.

FIG. 5 is a schematic sectional view for illustrating the schematic configuration of a composite substrate according to a third embodiment of the present disclosure.

FIG. 6A is a view for illustrating an example of a production process for a composite substrate according to one embodiment.

FIG. 6B is a view subsequent to FIG. 6A.

FIG. 6C is a view subsequent to FIG. 6B.

FIG. 6D is a view subsequent to FIG. 6C.

FIG. 6E is a view subsequent to FIG. 6D.

### DESCRIPTION OF THE EMBODIMENTS

Embodiments of the present disclosure are described below with reference to the drawings. However, the present disclosure is not limited to those embodiments. In order to further clarify the description, the width, thickness, shape, and the like of each portion may be schematically illustrated in the drawings as compared to the embodiments, but the illustration is merely an example and does not limit the interpretation of the present disclosure. In addition, in the drawings, the same or similar components are denoted by the same reference symbols, and repetitive description thereof may be omitted.

### A. Composite Substrate

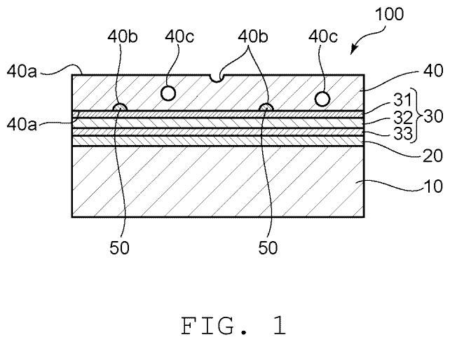

FIG. 1 is a schematic sectional view for illustrating the schematic configuration of a composite substrate according to a first embodiment of the present disclosure. A composite substrate 100 includes a support substrate 10, a joining layer 20, an electrode (lower electrode) 30, and a piezoelectric film 40 in the stated order. In the illustrated example, the lower electrode 30 includes a first lower electrode layer 31, a second lower electrode layer 32, and a third lower electrode layer 33 in the stated order from the piezoelectric film 40 side.

The composite substrate 100 may further include any appropriate layer (not shown). The kinds, functions, number, combination, arrangement, and the like of such layers may be appropriately set in accordance with purposes. For example, the composite substrate 100 may include an electrode (upper electrode) arranged on the piezoelectric film 40. The composite substrate 100 is typically used as an actuator, and for example, a wiring layer is formed on the upper electrode.

At an end portion of the piezoelectric film 40 in the thickness direction, a dissimilar material portion 50 including a material different from a material for forming the piezoelectric film 40 (hereinafter sometimes referred to as “dissimilar material”) is formed. The phrase “end portion in the thickness direction” as used herein means a part having a certain thickness. The dissimilar material portion 50 is formed in a recessed portion 40b in which an end surface 40a of the piezoelectric film 40 is recessed inward in the thickness direction. In this case, the dissimilar material includes not only a case of having different compositions, but also a case of having different crystal states and crystal structures. The piezoelectric film 40 includes a polycrystalline substance, and the piezoelectric film 40 may have, in addition to the recessed portion 40b, a space 40c formed apart from the recessed portion 40b. The dissimilar material portion 50 may be selectively formed in the recessed portion 40b. The recessed portion 40b has a diameter of, for example, from 1 μm to 6 μm. The space 40c has a diameter of, for example, from 1 μm to 6 μm. The diameters of the recessed portion and the space can be recognized by, for example, scanning electron microscope (SEM) observation. The term “diameter” as used herein means the maximum diameter of the cross section. Although not shown, the piezoelectric film 40 may have a through hole formed to pass through the piezoelectric film 40 from one end surface 40a to another end surface 40a. The through hole may include, for example, a form in which the above-mentioned recessed portions communicate with each other. In the following, a term of “hole” may be used as a generic term for a recessed portion, a space, and a through hole.

Forming the dissimilar material portion 50 at the end portion of the piezoelectric film 40 in the thickness direction may contribute to improvement of the reliability of the obtained composite substrate (piezoelectric element), and may allow excellent yield to be achieved. Specifically, charging any appropriate material to the recessed portion 40b that may be formed at the end portion of the piezoelectric film 40 in the thickness direction may contribute to improvement of the reliability of the obtained composite substrate (piezoelectric element), and may allow excellent yield to be achieved. When a hole is formed in the piezoelectric film 40, the reliability and the yield of the obtained composite substrate (piezoelectric element) may be reduced. For example, a distance between the upper electrode and the lower electrode arranged through intermediation of the piezoelectric film 40 may be reduced due to the presence of a hole to cause concentration of an electric field, and thus cracking may occur. Further, when a hole and a hole are caused to communicate with each other due to the occurrence of cracking or the like, a short circuit may occur. Such reduction in reliability and yield may become significant when the thickness of the piezoelectric film 40 is thin (e.g., when the thickness is 50 μm or less). Specifically, when the thickness of the piezoelectric film 40 is thin, the composite substrate (piezoelectric element) tends to be susceptible to the influence of the presence of the hole. With the dissimilar material portion 50 being formed at least at the end portion of the piezoelectric film 40 in the thickness direction, occurrence of such troubles can be suppressed.

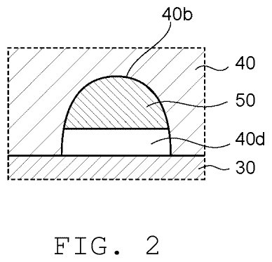

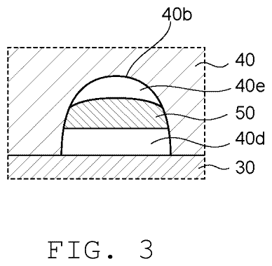

In the example illustrated in FIG. 1, the recessed portion 40b is filled with a dissimilar material, and the dissimilar material portion 50 is in contact with a layer or a member arranged adjacent to the piezoelectric film 40 (in the illustrated example, the electrode 30). The layer arranged adjacent to the piezoelectric film 40 may include an air layer and a vacuum layer. Unlike the example illustrated in FIG. 1, the recessed portion 40b is not required to be completely filled with the dissimilar material. For example, a gap may be formed adjacent to the dissimilar material portion 50. In the example illustrated in FIG. 2, a gap 40d is formed by being surrounded by the piezoelectric film 40, the dissimilar material portion 50, and the layer or the member arranged adjacent to the piezoelectric film 40 (in the illustrated example, the electrode 30). In the example illustrated in FIG. 3, in addition to the gap 40d as illustrated in FIG. 2, a gap 40e surrounded by the piezoelectric film 40 and the dissimilar material portion 50 is formed.

As illustrated, the dissimilar material portion 50 is only required to be formed at an end portion on at least one of the upper surface side or the lower surface side of the piezoelectric film 40, but the dissimilar material portion is preferably formed on both of the upper surface side and the lower surface side of the piezoelectric film.

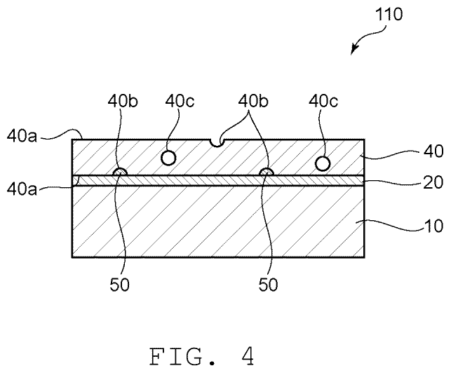

FIG. 4 is a schematic sectional view for illustrating the schematic configuration of a composite substrate according to a second embodiment of the present disclosure. A composite substrate 110 includes the support substrate 10, the joining layer 20, and the piezoelectric film 40 in the stated order. The second embodiment is different from the first embodiment in that the electrode 30 is arranged between the support substrate 10 (joining layer 20) and the piezoelectric film 40 in the first embodiment, but the electrode 30 is not arranged in the second embodiment. As in the first embodiment, the composite substrate 110 may include an electrode (upper electrode) arranged on the piezoelectric film 40.

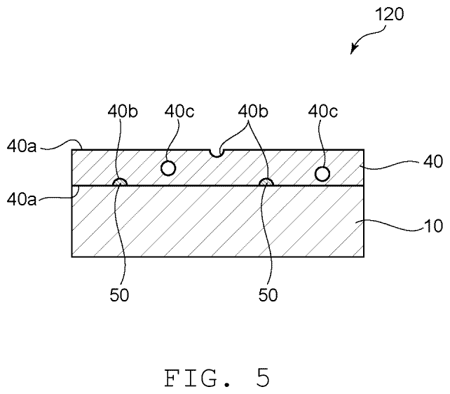

FIG. 5 is a schematic sectional view for illustrating the schematic configuration of a composite substrate according to a third embodiment of the present disclosure. A composite substrate 120 includes the support substrate 10 and the piezoelectric film 40. The third embodiment is different from the second embodiment in that the joining layer 20 is arranged between the support substrate 10 and the piezoelectric film 40 in the second embodiment, but the joining layer 20 is not arranged in the third embodiment. When the joining layer 20 is omitted, an amorphous region described later may be formed in an end portion of the piezoelectric film 40 on the support substrate 10 side, though the region is not shown.

In one embodiment, an electrode (lower electrode) may be formed on an exposed surface of the piezoelectric film 40 formed by removing the support substrate 10 and the joining layer 20 of the composite substrate 110, 120 through etching or the like.

The composite substrate may be produced in any appropriate shape. In one embodiment, the substrate may be produced in the form of a so-called wafer. The size of the composite substrate may be appropriately set in accordance with purposes. For example, the diameter of the wafer is from 50 mm to 200 mm.

The total thickness variation (TTV) of the composite substrate is preferably 10 μm or less, more preferably 5 μm or less, still more preferably 2 μm or less.

### A-1. Piezoelectric Film

The piezoelectric film includes a polycrystalline substance. The polycrystalline substance may be non-oriented. The term “non-oriented” as used herein refers to, for example, a degree of c-axis orientation determined by a Lotgering method of 80% or less, preferably 60% or less, more preferably 40% or less, still more preferably 20% or less, particularly preferably 10% or less. The piezoelectric film typically includes a sintered body. For example, a grain boundary is recognized in the piezoelectric film by TEM observation. A composite substrate in which the occurrence of a warp is suppressed can be obtained, for example, by adopting such configuration. Specifically, the piezoelectric film can be formed independently, and hence, for example, an internal stress is not generated through an interaction with another member at the time of formation of the piezoelectric film. In addition, when the piezoelectric film includes the above-mentioned polycrystalline substance, options for materials for forming the piezoelectric film are increased, and diversified characteristics can be supported. Specifically, characteristics, such as a piezoelectric constant, a dielectric constant, an electro-mechanical coupling coefficient, and a Curie temperature, can be finely adjusted in accordance with needs. Further, the piezoelectric film can be formed at low cost, which can contribute to improving the reliability of a composite substrate to be obtained.

The above-mentioned degree of c-axis orientation determined by a Lotgering method is a degree of (001) plane orientation F (001) calculated through use of the following expressions from an XRD profile obtained by measurement with an X-ray diffraction apparatus.

$$\begin{matrix}{F}_{( 001 )} = ( p - {p}_{0} ) / ( 1 - {p}_{0} ) \times 100 \\ p = \sum I ( 001 ) \sum I ( hkl ) \\ {p}_{0} = \sum {I}_{0} ( 001 ) / \sum {I}_{0} ( hkl )\end{matrix}$$

(I and I₀ each represent a diffraction intensity, and “p” and p₀ are each calculated from the ratio of diffraction intensities derived from a c-axis diffraction plane (001) to diffraction intensities of all diffraction planes (hkl). I and “p” each represent a value obtained from an XRD profile of the piezoelectric film (piezoelectric substrate), and I₀ and p₀ each represent a value obtained from an XRD profile of a sample obtained by powderizing the piezoelectric film (piezoelectric substrate).

Any appropriate ferroelectric is used as a material for forming the piezoelectric film. A lead zirconate titanate (PZT)-based compound is preferably used. Not only a binary PZT (PbZrO₃-PbTiO₃) of lead titanate and lead zirconate having a perovskite-type structure but also a ternary PZT may be used as the PZT-based compound. When the piezoelectric film includes the above-mentioned polycrystalline substance, the piezoelectric film may contain a ternary PZT. Through use of the ternary PZT, a composite substrate (piezoelectric element) to be obtained can be adapted to diversified characteristics. Specifically, characteristics, such as a piezoelectric constant, a dielectric constant, an electro-mechanical coupling coefficient, and a Curie temperature, can be finely adjusted in accordance with needs.

The atomic ratio (Zr/Ti) of Zr to Ti in the piezoelectric film is preferably 0.7 or more and 2.0 or less, more preferably 0.9 or more and 1.5 or less.

The ternary PZT is typically represented by ATiO₃—PbZrO₃—PbTiO₃ or PbBO₃—PbZrO₃—PbTiO₃, where A and B each represent an element except Pb, Zr, and Ti. Examples of the element A in the third component of the ternary PZT include Li, Na, K, Bi, La, Ce, and Nd. Examples of the element B in the third component of the ternary PZT include Li, Cu, Mg, Ni, Zn, Mn, Co, Sn, Fe, Cd, Sb, Al, Yb, In, Sc, Y, Nb, Ta, Bi, W, Te, and Re. Those elements may be used alone or in combination thereof.

The proportion of the third component with respect to the sum of Zr, Ti, Pb, and the third component (element A and/or element B) in the piezoelectric film, specifically, the atomic ratio “third component/(Zr+Ti+Pb+third component)” is preferably 0.05 or more and 0.25 or less, more preferably 0.10 or more and 0.20 or less.

The atomic ratio (proportion) may be determined through composition analysis by energy dispersive X-ray spectroscopy (EDX).

Other specific examples of the material for forming the piezoelectric film include PMN-PT (Pb(Mg_{1/3}Nb_{2/3})O₃—PbTiO₃), barium titanate (BaTiO₃), lead titanate (PbTiO₃), lead metaniobate (PbNb₂O₆), bismuth titanate (Bi₄Ti₃O₁₂), KNN ((K_{0.5}Na_{0.5})NbO₃), KNN-LN (((K_{0.5}Na_{0.5})NbO₃)—LiNbO₃), and BT-BNT-BKT ((Bi_{0.5}Na_{0.5})TiO₃—(Bi_{0.5}K_{0.5})TiO₃—BaTiO₃).

The thickness of the piezoelectric film is, for example, more than 0.2 μm, preferably 0.3 μm or more, more preferably 1 μm or more, still more preferably 3 μm or more. In one embodiment, the thickness of the piezoelectric film may be 5 μm or more or 6 μm or more. With such thickness, for example, a low-voltage-driven actuator with high displacement can be obtained. For example, when the piezoelectric film is formed by film formation such as sputtering, it is difficult to achieve such thickness in view of the film stress, productivity, and the like of the piezoelectric film to be obtained. In contrast, when the piezoelectric film includes the above-mentioned polycrystalline substance, the piezoelectric film can be set to have such thickness. In addition, when the piezoelectric film includes the above-mentioned polycrystalline substance, a composite substrate in which the occurrence of a warp is suppressed can be obtained even with such thickness. Meanwhile, the thickness of the piezoelectric film is, for example, 200 μm or less, preferably 150 μm or less, more preferably 100 μm or less, still more preferably 50 μm or less, particularly preferably 40 μm or less, and may be 20 μm or less. With such thickness, for example, a low-voltage-driven and small-sized actuator can be obtained. Further, with such thickness, defects caused by a difference in thermal expansion from the support substrate (e.g., occurrence of cracking caused by heating) can be suppressed, and for example, a heating process (e.g., 100° C. or more) in the production of a piezoelectric device can be supported. Specifically, mask formation using photolithography or the like in the production of a MEMS device can be supported.

As described above, the piezoelectric film may include a sintered body. The sintered body may be formed by any appropriate method. In one embodiment, the sintered body may be formed by subjecting raw material powder to pressure sintering. As a specific example, the sintered body may be formed by subjecting raw material powder mixed at a predetermined blending ratio or powder obtained by calcining raw material powder mixed at a predetermined blending ratio and then pulverizing the resultant to a predetermined particle diameter (e.g., from 0.1 μm to 10 μm) to pressure sintering. Any appropriate method may be adopted as the pressure sintering. Specifically, a HIP method, a hot press method, or the like may be adopted.

The piezoelectric film can be obtained by subjecting the piezoelectric substrate to processing, such as grinding or polishing, to obtain a desired thickness. For example, the piezoelectric film can be obtained by subjecting the piezoelectric substrate including the sintered body to processing, such as grinding or polishing, to obtain a desired thickness. In the formation of the piezoelectric film, polarization treatment is performed at any appropriate timing. In one embodiment, a pair of electrodes are respectively arranged on facing surfaces of the piezoelectric substrate (e.g., a sintered body formed in a plate shape), and polarization treatment is performed on the piezoelectric substrate by an electric field in a direction from one electrode to the other electrode. After that, the resultant is subjected to the processing, such as grinding or polishing, to thereby provide a piezoelectric film.

The above-mentioned hole may be generated at the time of, for example, sintering of the raw material powder. Further, for example, the above-mentioned hole may be generated by shedding or the like in the processing of bringing the piezoelectric substrate to a desired thickness (forming the piezoelectric film).

The arithmetic average roughness Ra of the piezoelectric film is preferably 2 nm or less, more preferably 1 nm or less, still more preferably 0.3 nm or less.

The dissimilar material portion may be formed of any appropriate material. The dissimilar material may be an inorganic material or an organic material. Examples of the inorganic material include an oxide, a nitride, and a carbon-based material. Examples of the oxide include silicon oxide, niobium oxide, titanium oxide, tantalum oxide, hafnium oxide, aluminum oxide, a PZT-based compound, barium titanate, lead titanate, lead metaniobate, bismuth titanate, and KNN. Examples of the nitride include silicon nitride, aluminum nitride, and gallium nitride. Examples of the carbon-based material include silicon carbide and diamond. As the organic material, there is used, for example: a resin composition, such as a thermosetting resin composition, a photocurable resin composition, or a photosensitive resin composition; or a heat-resistant resin typified by a polyimide-based resin. In addition, benzocyclobutene (BCB) may be used as the organic material. Those materials may be used alone or in combination thereof. Specific examples of a form in which the inorganic material and the organic material are combined include a form in which an inorganic material is dispersed in a resin composition. For example, spin-on glass can be used. When an inorganic material is used, its crystal state or crystal structure is not particularly limited. Specifically, the inorganic material may be a single crystalline substance, a polycrystalline substance, an amorphous (e.g., glass), or a composite thereof. Further, the inorganic material may be used to form a porous body.

In one embodiment, a material satisfying a predetermined dielectric constant is selected as the material for forming the dissimilar material portion, depending on the shape, layout, or the like of the dissimilar material portion.

### A-2. Support Substrate

Any appropriate substrate may be used as the support substrate. The support substrate may include a single crystalline substance, or may include a polycrystalline substance. In addition, the support substrate may include a metal. A material for forming the support substrate is preferably selected from the group consisting of: silicon; sialon; sapphire; cordierite; mullite; glass; quartz; crystal; alumina; SUS; an iron-nickel alloy (42 alloy); and brass.

The silicon may be single crystalline silicon, polycrystalline silicon, or high resistance silicon. The support substrate may be silicon on insulator (SOI).

Typically, the sialon is a ceramic obtained by sintering a mixture of silicon nitride and alumina, and has composition represented for by, example, Si_{6-w}Al_{w}O_{w}N_{8-w}. Specifically, the sialon has such composition that alumina is mixed into silicon nitride, and “w” in the formula represents the mixing ratio of alumina. “w” preferably represents 0.5 or more and 4.0 or less.

Typically, the sapphire is a single crystalline material having the composition of Al₂O₃, and the alumina is a polycrystalline material having the composition of Al₂O₃. The alumina is preferably translucent alumina.

Typically, the cordierite is a ceramic having the composition of 2MgO·2Al₂O₃·5SiO₂, and the mullite is a ceramic having composition in the range of from 3Al₂O₃·2SiO₂ to 2Al₂O₃·SiO₂.

Any appropriate thickness may be adopted as the thickness of the support substrate. The thickness of the support substrate is, for example, from 100 μm to 1,000 μm.

### A-3. Joining Layer

A material for forming the joining layer, which may be incorporated into the composite substrate, is, for example, silicon, tantalum oxide, niobium oxide, aluminum oxide, titanium oxide, or hafnium oxide. The thickness of the joining layer is, for example, from 5 nm to 1 μm, preferably from 10 nm to 200 nm.

The joining layer typically includes an amorphous substance. Specifically, the joining layer may be an amorphous layer. When the joining layer includes an amorphous substance, for example, the polishing described later is easily performed, and a preferred surface roughness is easily obtained on a joining surface.

The joining layer may be formed by any appropriate method. The joining layer may be formed by, for example, physical deposition, such as sputtering, vacuum deposition, or ion beam assisted deposition (IAD), chemical deposition, or an atomic layer deposition (ALD) method. The formation of the joining layer may be performed at, for example, from room temperature (25° C.) to 300° C.

### A-4. Electrode

In the illustrated example, the electrode (lower electrode) has a laminated structure including the first lower electrode layer, the second lower electrode layer, and the third lower electrode layer. The first lower electrode layer and the third lower electrode layer, which are brought into contact with the layers adjacent to the electrode, may each function as an adhesion layer. For example, a metal, such as Ti, Cr, Ni, Mo, or Al, is used as a material for forming each of the first lower electrode layer and the third lower electrode layer. Those metals may be used alone or in combination thereof.

In one embodiment, the material for forming the first lower electrode layer and the material for forming the third lower electrode layer are substantially identical to each other. Specifically, the first lower electrode layer and the third lower electrode layer have substantially the same composition. For example, the first lower electrode layer includes a metal (e.g., Ti), and the third lower electrode layer includes a metal (e.g., Ti). Such configuration can be adopted when the piezoelectric film includes the above-mentioned polycrystalline substance. For example, when the piezoelectric film is formed by film formation, the adjacent layer (electrode) functions as a seed crystal layer for the piezoelectric film and includes a material having predetermined physical properties (e.g., a lattice constant). In contrast, when the piezoelectric film includes the above-mentioned polycrystalline substance, options for the material for forming the adjacent layer (electrode) are increased, and a material may be selected, for example, from the viewpoints of production efficiency, the characteristics of a composite substrate (piezoelectric element) to be obtained, and the like.

The thickness of each of the first lower electrode layer and the third lower electrode layer, which may function as adhesion layers with the adjacent layers, is, for example, 1 nm or more and 100 nm or less, preferably 3 nm or more and 50 nm or less, more preferably 5 nm or more and 20 nm or less.

A metal, such as Pt or Au, is preferably used as a material for forming the second lower electrode layer. The thickness of the second lower electrode layer is, for example, 10 nm or more and 1,000 nm or less, preferably 50 nm or more and 250 nm or less.

The electrode (second lower electrode layer) typically includes an amorphous substance. Such configuration may contribute to, for example, the suppression of a warp that occurs in a composite substrate to be obtained.

The electrode may be formed by any appropriate method. For example, the electrode may be formed by physical vapor deposition, such as sputtering, vacuum deposition, or ion beam assisted deposition (IAD). In one embodiment, the first lower electrode layer and the third lower electrode layer may be formed by sputtering under the same conditions through use of the same target (e.g., a Ti target). The formation of the electrode may be performed at, for example, from room temperature (25° C.) to 300° C.

### A-5. Production Method

The above-mentioned composite substrate may be obtained, for example, joining (directly joining) the above-mentioned piezoelectric film or piezoelectric substrate and the above-mentioned support substrate to each other.

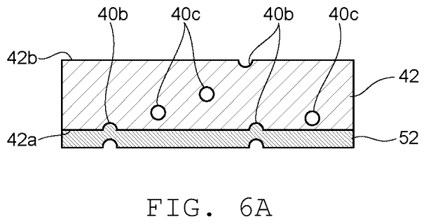

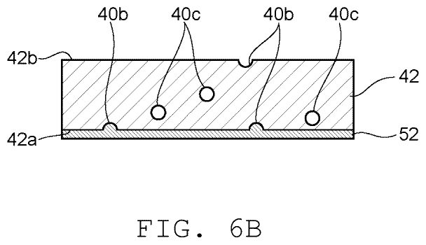

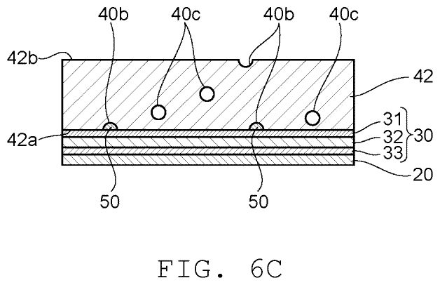

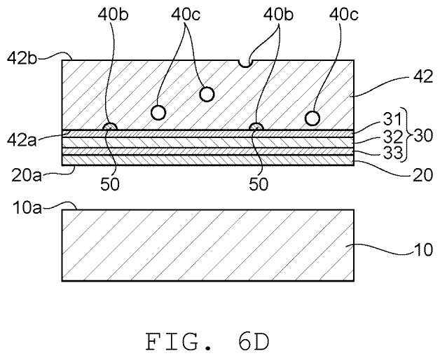

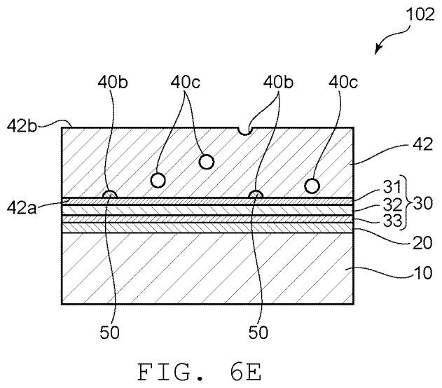

FIG. 6A to FIG. 6E are each a view for illustrating an example of a production process for a composite substrate according to one embodiment. FIG. 6A is an illustration of a state in which lamination of a dissimilar material layer 52 on a piezoelectric substrate 42 is completed. The prepared piezoelectric substrate 42 has a first main surface 42a and a second main surface 42b facing each other. The dissimilar material layer 52 is laminated on the first main surface 42a. At the time of lamination, a dissimilar material may be charged to the recessed portion 40b formed at the end portion of the piezoelectric substrate 42 in the thickness direction. The term “charging” as used herein is not always required to mean entirely filling the recessed portion 40b with the dissimilar material.

Any appropriate method may be adopted as the method of laminating the dissimilar material layer 52 or the method of charging the dissimilar material to the recessed portion 40b (hereinafter referred to as “laminating method”). Examples of the laminating method include film formation such as chemical deposition and physical deposition, such as sputtering, vacuum deposition, and ion beam assisted deposition (IAD). Other examples of the laminating method include a method including printing, immersing, or applying (e.g., applying by a spin coating method) a fluid including a dissimilar material or a precursor thereof, and performing post-processing (e.g., drying, firing, or curing processing) as required. It is preferred that the fluid including the dissimilar material or the precursor thereof not substantially include moisture from the viewpoint of suppressing an adverse effect to the subsequent steps.

The thickness of the dissimilar material layer 52 is preferably more than 50 nm, more preferably 100 nm or more, still more preferably 500 nm or more, particularly preferably 1,000 nm or more. With such thickness, the dissimilar material may be more reliably charged to the recessed portion 40b.

FIG. 6B is an illustration of a step of removing the laminated dissimilar material layer 52 by polishing or the like. The dissimilar material layer 52 may be removed to reach the first main surface 42a of the piezoelectric substrate 42, or, as illustrated in FIG. 6B, the removal of the dissimilar material layer 52 may be stopped at a stage at which the dissimilar material layer 52 covers the entire first main surface 42a of the piezoelectric substrate 42. In the latter case, the finally obtained end surface of the piezoelectric film in the thickness direction is covered with the dissimilar material portion formed to extend from the recessed portion 40b.

FIG. 6C is an illustration of a state in which, after the dissimilar material layer 52 is removed to reach the first main surface 42a of the piezoelectric substrate 42, formation of the electrode 30 and the joining layer 20 on the piezoelectric substrate 42 is completed. Even after the dissimilar material layer 52 is removed, the recessed portion 40b is filled with the dissimilar material, and the dissimilar material portion 50 is formed. Then, on the first main surface 42a side of the piezoelectric substrate 42, the first lower electrode layer 31, the second lower electrode layer 32, and the third lower electrode layer 33 are sequentially formed to form the electrode 30, and then the joining layer 20 is formed.

In this production process example, the formation of the dissimilar material portion 50 (lamination of the dissimilar material layer 52) is performed only on the first main surface 42a side of the piezoelectric substrate 42, but may be performed also on the second main surface 42b side, or may be performed only on the second main surface 42b side without being performed on the first main surface 42a side. Further, in this production process example, the dissimilar material layer 52 is removed, but the dissimilar material layer 52 is not required to be removed. For example, when a joining layer (not shown) is provided after the dissimilar material layer 52 is laminated, the dissimilar material layer 52 is not required to be removed.

FIG. 6D is an illustration of the step of directly joining the piezoelectric substrate 42 having the electrode 30 and the joining layer 20 formed thereon and the support substrate 10 to each other. At the time of the direct joining, the joining surfaces of the layer and the substrate are preferably activated by any appropriate activation treatment. The direct joining is performed by, for example, activating a surface 20a of the joining layer 20, activating a surface 10a of the support substrate 10, then bringing the activated surface of the joining layer 20 and the activated surface of the support substrate 10 into contact with each other, and pressurizing the resultant. Thus, a composite substrate 102 illustrated in FIG. 6E is obtained.

In one embodiment, an end portion of the joining layer 20 on the activated surface side and/or an end portion of the support substrate 10 on the activated surface side contains an element (e.g., argon) for forming a gas to be used in the activation treatment. Specifically, the end portion of the joining layer 20 and/or the support substrate 10 on the activated surface side is turned into an amorphous region (region containing an amorphous substance) containing an element for forming a gas to be used in the activation treatment. The thickness of such amorphous region is, for example, from 2 nm to 30 nm. The argon concentration of the amorphous region is, for example, from 0.5 atm % to 30 atm %. Although the distribution state of argon in the amorphous region is not particularly limited, for example, in the amorphous region, the argon concentration is increased toward the activated surface side.

The second main surface 42b of the piezoelectric substrate 42 of the resultant composite substrate 102 is typically subjected to processing, such as grinding or polishing, so that a piezoelectric film having the above-mentioned desired thickness is obtained. In one embodiment, the processing, such as grinding or polishing, is performed so that the thickness of a piezoelectric film to be obtained is more than 0.2 μm. According to such form, the grain boundary binding force of a piezoelectric film to be obtained and the binding force with the support substrate are not weakened by the processing load, and the shedding of crystals for forming the piezoelectric film and the occurrence of peeling of the piezoelectric film can be suppressed. When the formation of the dissimilar material portion 50 (lamination of the dissimilar material layer 52) is performed on the second main surface 42b side of the piezoelectric substrate 42, for example, the formation of the dissimilar material portion 50 (lamination of the dissimilar material layer 52) may be performed after subjecting the second main surface 42b to processing, such as grinding or polishing.

The surface of each layer (specifically, the piezoelectric film or the piezoelectric substrate, the support substrate, or the joining layer) is preferably a flat surface. Specifically, the arithmetic average roughness Ra of the surface of each layer is, for example, 5 nm or less, preferably 2 nm or less, more preferably 1 nm or less, still more preferably 0.3 nm or less. A method of flattening the surface of each layer is, for example, mirror polishing through chemical-mechanical polishing (CMP) or lap polishing.

At the time of the film formation and the joining described above, the surface of each layer is preferably washed for, for example, removing the residue of a polishing agent. A method for the washing is, for example, wet washing, dry washing, or scrub washing. Of those, scrub washing is preferred because the surface can be simply and efficiently washed. A specific example of the scrub washing is a method including washing the surface in a scrub washing machine with a detergent (e.g., a SUNWASH series manufactured by Lion Corporation) and then with a solvent (e.g., a mixed solution of acetone and isopropyl alcohol (IPA)).

The activation treatment is typically performed by irradiating the surface with a neutralized beam. The activation treatment is preferably performed by generating the neutralized beam with an apparatus such as an apparatus as described in JP 2014-086400 A, and irradiating the surface with the beam. Specifically, a saddle-field fast atomic beam source is used as a beam source, and an inert gas, such as argon or nitrogen, is introduced into the chamber of the source, followed by the application of a high voltage from a DC power source thereof to an electrode thereof. Thus, a saddle-field electric field is generated between the electrode (positive electrode) and the casing (negative electrode) thereof to cause electron motion, to thereby generate the beams of an atom and an ion by the inert gas. Of the beams that have reached the grid of the apparatus, an ion beam is neutralized by the grid, and hence the beam of a neutral atom is emitted from the fast atomic beam source. The voltage at the time of the activation treatment by the beam irradiation is preferably set to from 0.5 kV to 2.0 kV, and a current at the time of the activation treatment by the beam irradiation is preferably set to from 50 mA to 200 mA.

The joining surfaces are preferably brought into contact with each other and pressurized in a vacuum atmosphere. A temperature at this time is typically normal temperature. Specifically, the temperature is preferably 20° C. or more and 40° C. or less, more preferably 25° C. or more and 30° C. or less. A pressure to be applied is preferably from 100 N to 20,000 N.

In the illustrated example, the composite substrate is obtained by joining the piezoelectric substrate having the electrode and the joining layer formed thereon and the support substrate to each other, but the present disclosure is not limited to such form. For example, the support substrate and the piezoelectric substrate (piezoelectric film) may be joined to each other after the layers (e.g., the electrode and the joining layer) that may be arranged between the piezoelectric film and the support substrate have been arranged on the support substrate side. Specifically, the composite substrate may include an argon-containing amorphous layer, which is located between the piezoelectric film and the support substrate, and which contains argon. The argon-containing amorphous layer may correspond to the above-mentioned amorphous region.

### EXAMPLES

The present disclosure is specifically described below by way of Examples. However, the present disclosure is not limited by these Examples. Unless otherwise stated, the following procedure was performed at room temperature.

### Example 1

PbZrO₃ powder, PbTiO₃ powder, Nb₂O₅ powder, and Zno powder were mixed under stirring in a ball mill through use of water as a dispersion material, and the resultant mixture was dried, and was calcined (at 900° C. for 2 hours) in the atmosphere. After that, the resultant was subjected to wet pulverization in the ball mill again for 20 hours to provide powder having a particle diameter of about 1 μm. Then, the powder was subjected to press forming to provide a compact.

The resultant compact was subjected to preliminary firing at 1,250° C. for 2 hours in the atmosphere. After the firing, the resultant was cooled in the atmosphere to provide a preliminary fired body. The resultant preliminary fired body was embedded in a container filled with mixed powder of PbO and ZrOz, and the top of the container was covered with a lid. The container was placed in an internal heating high-temperature and high-pressure furnace, and a temperature in the furnace was increased from room temperature to 1,100° C. over 4.5 hours. Thus, hot isostatic pressing treatment (HIP method) was performed. Specifically, the hot isostatic pressing treatment was performed as follows: at the time of the increase in temperature, a pressure was applied up to 280 bar at 1,000° C., and the pressure was increased from 280 bar to 600 bar in 1 hour from the time point when the temperature exceeded 1,000° C., and the resultant was kept at 1,100° C. and 600 bar for 1 hour. Thus, a plate-shaped sintered body was obtained.

An electrode was formed on each of the upper surface and the lower surface of the resultant sintered body, and the sintered body was subjected to polarization treatment through application of a predetermined voltage. After that, the sintered body was subjected to beveling, grinding, and lap polishing processing to provide a wafer (piezoelectric substrate) having a first surface and a second surface facing each other, and having a diameter of 4 inches and a thickness of 500 μm.

The degree of c-axis orientation of the resultant piezoelectric substrate was determined to be 2% by the Lotgering method. The degree of c-axis orientation is a degree of (001) plane orientation Fool) calculated through use of the following expressions from an XRD profile measured with an XRD apparatus when the surface (orientation surface) of the piezoelectric substrate was irradiated with an X-ray. The evaluation was performed in the range of a diffraction angle 2θ of from 10° to 80°.

$$\begin{matrix}{F}_{( 001 )} = ( p - {p}_{0} ) / ( 1 - {p}_{0} ) \times 100 \\ p = \sum I ( 001 ) \sum I ( hkl ) \\ {p}_{0} = \sum {I}_{0} ( 001 ) / \sum {I}_{0} ( hkl )\end{matrix}$$

(I and I₀ each represent a diffraction intensity, and “p” and p₀ are each calculated from the ratio of diffraction intensities derived from a c-axis diffraction plane (001) to diffraction intensities of all diffraction planes (hkl). I and “p” each represent a value obtained from an XRD profile when the surface (orientation surface) of the piezoelectric substrate is irradiated with an X-ray, and I₀ and p₀ each represent a value obtained from an XRD profile when a sample obtained by powderizing the piezoelectric substrate is measured.)

The first surface of the resultant piezoelectric substrate was subjected to finishing by chemical-mechanical polishing (CMP) to be mirror-finished so that the arithmetic average roughness Ra was less than 2 nm. Herein, the arithmetic average roughness Ra is a value measured with an atomic force microscope (AFM) in a field of view measuring 10 μm by 10 μm.

When the mirror-finished first surface of the piezoelectric substrate was observed with a scanning electron microscope (SEM) (magnification: 500×), about one hole (recessed portion) having a diameter of 3 μm or more was recognized per 4 mm² to 6 mm².

A tantalum oxide (Ta₂O₅) film having a thickness of 100 nm was formed on the mirror-finished first surface of the piezoelectric substrate by sputtering. Specifically, the mirror-finished piezoelectric substrate was introduced into a chamber of a sputtering apparatus (“RAS-1100BII” manufactured by Shincron Co., Ltd.), a Ta target was used, and an oxygen gas was introduced into the chamber as an oxygen source. An oxygen gas introduction amount was adjusted to adjust the oxygen partial pressure and the entire pressure of the atmosphere in the chamber. Film formation was performed under the following conditions.
Rate: 0.3 nm/sec
Pressure in chamber at film formation: 0.3 Pa

After that, the tantalum oxide film was subjected to chemical-mechanical polishing (CMP) to remove the tantalum oxide film (thickness: 100 nm) and expose the first surface of the piezoelectric substrate. The exposed first surface had an arithmetic average roughness Ra of 1 nm. Here, it was confirmed that tantalum oxide was left in the recessed portion present in the first surface of the piezoelectric substrate.

On the first surface of the piezoelectric substrate from which the tantalum oxide film has been removed, a Ti film having a thickness of 10 nm, a Pt film having a thickness of 100 nm, a Ti film having a thickness of 10 nm, and a silicon film having a thickness of 150 nm were formed by sputtering in the stated order, thereby forming the lower electrode and the joining layer. After that, the surface of the silicon film was subjected to chemical-mechanical polishing (CMP) to achieve an arithmetic average roughness Ra of 0.2 nm.

A silicon substrate including an orientation flat portion, and having a diameter of 4 inches and a thickness of 500 μm was prepared. The surface of the silicon substrate was subjected to chemical-mechanical polishing (CMP), and had an arithmetic average roughness Ra of 0.2 nm.

Next, the piezoelectric substrate and the support substrate were directly joined to each other. Specifically, the surface (silicon film side) of the piezoelectric substrate and the surface of the silicon substrate were washed, and then both the substrates were loaded into a vacuum chamber, followed by its evacuation to a vacuum of the order of 10⁻⁶ Pa. After that, the surfaces of both the substrates were irradiated with fast atomic beams (acceleration voltage: 1 kV, Ar flow rate: 27 sccm) for 120 seconds. After the irradiation, the beam-irradiated surfaces of both the substrates were superimposed on each other, and both the substrates were joined to each other by being pressurized at 10,000 N for 2 minutes to provide a joined body.

Then, the second surface of the piezoelectric substrate of the resultant joined body was subjected to grinding and polishing. Thus, a composite substrate including a piezoelectric film having a thickness of 5 μm was obtained.

### Example 2

A composite substrate was obtained in the same manner as in Example 1 except that the formation of the tantalum oxide film and the removal by polishing were performed on the polished second surface instead of the first surface of the piezoelectric substrate.

### Example 3

A composite substrate was obtained in the same manner as in Example 1 except that the formation of the tantalum oxide film and the removal by polishing were performed also on the polished second surface similarly to the first surface of the piezoelectric substrate.

### Example 4

A composite substrate was obtained in the same manner as in Example 1 except that the thickness of the tantalum oxide film to be formed and polished was changed to 500 nm.

### Example 5

A composite substrate was obtained in the same manner as in Example 4 except that the formation of the tantalum oxide film and the removal by polishing were performed on the polished second surface instead of the first surface of the piezoelectric substrate.

### Example 6

A composite substrate was obtained in the same manner as in Example 4 except that the formation of the tantalum oxide film and the removal by polishing were performed also on the polished second surface similarly to the first surface of the piezoelectric substrate.

### Example 7

A composite substrate was obtained in the same manner as in Example 1 except that the thickness of the tantalum oxide film to be formed and polished was changed to 1,500 nm.

### Example 8

A composite substrate was obtained in the same manner as in Example 7 except that the formation of the tantalum oxide film and the removal by polishing were performed on the polished second surface instead of the first surface of the piezoelectric substrate.

### Example 9

A composite substrate was obtained in the same manner as in Example 7 except that the formation of the tantalum oxide film and the removal by polishing were performed also on the polished second surface similarly to the first surface of the piezoelectric substrate.

### Comparative Example 1

A composite substrate was obtained in the same manner as in Example 1 except that the formation of the tantalum oxide film and the removal by polishing were not performed on the first surface of the piezoelectric substrate.

The composite substrates of Examples and Comparative Examples were evaluated as described below. The evaluation results are summarized in Table 1.

### <Evaluation>

An upper electrode was formed by forming, on the upper surface of the piezoelectric film of the obtained composite substrate (wafer), a Ti film having a thickness of 10 nm and a Pt film having a thickness of 100 nm by sputtering in the stated order.

Through use of photolithography and wet etching, the upper electrode was patterned so that one hundred pads each having a size of 2 mm×2 mm were formed. After that, in each pad, a part of the piezoelectric film was removed by wet etching to expose the lower electrode.

The exposed lower electrode and the upper electrode were connected to a + terminal and a − terminal of a tester to measure a resistance value. In a case of a short circuit, the resistance value represented about 10Ω. The number of short-circuited pads was measured to calculate a short-circuit occurrence rate (failure occurrence rate).

TABLE 1

| | Tantalum oxide film | | Failure |
|---|---|---|---|
| | Film formation | Film formation | occurrence |
| | thickness (nm) | surface | rate (%) |
| Example 1 | 100 | First surface | 59 |
| Example 2 | 100 | Second surface | 49 |
| Example 3 | 100 | First and second | 20 |
| | | surfaces | |
| Example 4 | 500 | First surface | 30 |
| Example 5 | 500 | Second surface | 26 |
| Example 6 | 500 | First and second | 5 |
| | | surfaces | |
| Example 7 | 1,500 | First surface | 5 |
| Example 8 | 1,500 | Second surface | 3 |
| Example 9 | 1,500 | First and second | 0 |
| | | surfaces | |
| Comparative | — | — | 80 |
| Example 1 | | | |

The composite substrate (after the upper electrode is formed) of Comparative Example 1 was observed with a scanning electron microscope (SEM) (magnification: 500×), and about one short-circuit portion was recognized per 5 mm² to 7 mm².

The composite substrate according to the embodiment of the present disclosure can be suitably used in a piezoelectric element. The piezoelectric element is used in a piezoelectric device, such as an ink jet head, a MEMS mirror device, a gyroscope sensor, an ultrasonic sensor, a pyroelectric infrared sensor, or a haptic sensor (haptic).

What is claimed is:

1. A composite substrate, comprising:
a support substrate; and
a piezoelectric film which is arranged above the support substrate, and includes a polycrystalline substance,
wherein a dissimilar material portion including a material different from a material for forming the polycrystalline substance is formed at an end portion on at least one of an upper surface side or a lower surface side of the piezoelectric film.

2. The composite substrate according to claim 1, wherein the dissimilar material portion is formed in a recessed portion in which an end surface of the piezoelectric film is recessed inward in a thickness direction.

3. The composite substrate according to claim 1, wherein the piezoelectric film has a space formed apart from the dissimilar material portion.

4. The composite substrate according to claim 1, wherein the dissimilar material portion has a gap formed adjacent thereto.

5. The composite substrate according to claim 1, wherein the dissimilar material portion is in contact with a layer or a member arranged adjacent to the piezoelectric film.

6. The composite substrate according to claim 1, wherein the piezoelectric film includes a polycrystalline substance having a degree of c-axis orientation determined by a Lottering method of 80% or less.

7. The composite substrate according to claim 1, wherein the piezoelectric film includes a sintered body.

8. The composite substrate according to claim 1, wherein the piezoelectric film contains a PZT-based compound.

9. The composite substrate according to claim 1, wherein the piezoelectric film contains a ternary PZT.

10. The composite substrate according to claim 1, wherein the piezoelectric film has a thickness of 1 μm or more and 50 μm or less.

11. A piezoelectric device, comprising the composite substrate of claim 1.

12. A method of producing a composite substrate, comprising:
preparing a piezoelectric substrate including a sintered body and having an upper surface and a lower surface that face each other;
laminating a dissimilar material layer including a material different from a material for forming the piezoelectric substrate on a side of at least one of the upper surface or the lower surface of the piezoelectric substrate to charge a dissimilar material to a recessed portion formed at an end portion of the piezoelectric substrate in a thickness direction; and
joining the piezoelectric substrate and a support substrate to each other.

13. The method of producing a composite substrate according to claim 12, further comprising removing, in the thickness direction, at least a part of the laminated dissimilar material layer.
